(19) United States
(12) Patent Application Publication
(10) Pub. No.: US 2007/0272653 A1
(43) Pub. Date: Nov. 29, 2007

(54) Method for Orientation Treatment of Electronic Functional Material and Thin Film Transistor

(76) Inventor: Naohide Wakita, Osaka (JP)

Correspondence Address: MCDERMOTT WILL & EMERY LLP, 600 13TH STREET, NW, WASHINGTON, DC, 20005-3096, US

(21) Appl. No.: 10/578,713

(22) PCT Filed: Nov. 9, 2004
(86) PCT No.: PCT/JP04/16574

§ 371 Date: Jan. 17, 2007

(30) Foreign Application Priority Data
Nov. 10, 2003 (JP) 2003-379729

(51) Int. Cl. H01L 51/00; B82B 3/00; H01L 29/06; H01L 29/786

(52) U.S. Cl. 216/13; 156/47; 23/294 R

(57) ABSTRACT

A method of orienting an electronic functional material which comprises: a mixed material preparation step (Step S1) of preparing a mixed material from an electronic functional material and a matrix material used for orientating the electronic functional material; an orientation step (Step S2) of orientating the mixed material; and a matrix material removal step (Step S3) of removing the matrix material from the mixed material which has been oriented.

### TECHNICAL FIELD

The present invention relates to an orientation method for electronic functional material such as organic semiconductors and nanotubes and a thin film transistor having a semiconductor layer formed by the orientation method.

### BACKGROUND ART

In recent years, there has arisen a possibility that use of organic electronic functional material such as organic semiconductors could realize fabrication of thin-film devices through a process at room temperature or at a low temperature in the vicinity thereof without use of costly equipment required for high-temperature processes using silicon. Examples of such thin-film devices include organic semiconductor thin-film transistors (Organic TFT) which utilize organic semiconductors composed of organic compounds having the characteristics of semiconductors and organic electroluminescence devices (Organic EL). If a plastic substrate or resin film having mechanical flexibility and pliability is used as the substrate of such thin-film devices, sheet-like or paper-like displays and electronic equipment will be put into practice.

One example of known organic base electronic functional material technologies is organic semiconductors composed of organic compounds (e.g., polythiophene base high polymer organic semiconductor material) which exclude molecular crystals. These semiconductors still have low carrier mobilities of 0.003 to 0.01 cm²/Vs and are therefore impractical. Low-molecular organic semiconductor materials such as pentacene exhibit a carrier mobility of about 0.3 cm²/Vs, nevertheless their carrier mobility should be more improved in order that thin-film transistors in which they are used at least as the semiconductor layer is put into practice.

Nanotubes (NT) of nanostructure and, more particularly, carbon nanotubes (CNT) which are inorganic electronic functional material made from carbon (C) are excellent in electric conductivity as well as in mechanical strength. Further, they are chemically, thermally stable. Therefore, many researches have been made into them in these days. Carbon nanotubes have minimal diameters on the order of nanometers and lengths on the order of microns. Their aspect ratios are extremely high and unlimitedly close to an ideal one-dimensional system. According to their diameters and helix degrees which are dependent on the symmetric property of their molecular structures, carbon nanotubes are classified into two types, i.e., metallic nanotubes of high electric conductivity and nanotubes having semiconducting characteristics and band gaps inversely proportional to their diameters. Usually, carbon nanotubes are produced in the form of a carbon nanotube mixture containing metallic nanotubes and semiconductive nanotubes which are blended, for example, at a ratio of about 1:2. Therefore, where carbon nanotubes are utilized as the semiconductor layer of a thin-film transistor such as described above, semiconductive nanotubes need to be used. The thin-film transistors having semiconductive nanotubes as the semiconductor layer exhibit carrier mobilities as high as 1000 to 1500 cm²/Vs in their channels.

As a technique that uses such semiconductive carbon nanotubes of high carrier mobility, there has been previously reported a study of nanotube base thin-film transistors according to which carbon nanotubes having a diameter of about 1.6 nm are arranged to form a semiconductor layer that is about 1.6 nm in thickness (see e.g., Nonpatent Document 1).

FIG. 7 is a sectional view conceptually showing a configuration of a prior art thin-film transistor that uses carbon nanotubes as a semiconductor layer. As shown in FIG. 7, in this prior art thin-film transistor 60, a 140 nm-thick gate insulating film 62 made from oxide silicon is formed on a doped silicon substrate 61 that serves as a gate electrode as well, and a source electrode 64 and drain electrode 65, which are made from gold (Au), are laid over the gate insulating film 62 such that these electrodes 64, 65 face each other. Carbon nanotubes 63 are arranged on the gate insulating film 62 in the form of a semiconductor layer extending as if it bridges the source electrode 64 and the drain electrode 65. The carbon nanotubes 63 are semiconductive and 1.6 nm in diameter. The carbon nanotubes 63 are arranged by operating the manipulator of an atomic force microscope (AFM). In this way, the thin-film transistor 60 makes use of, as a semiconductor layer, the carbon nanotubes 63 that are an inorganic electronic functional material.

There has been known another prior art technique for orienting carbon nanotubes (see e.g., Patent Document 1). In this prior art technique, high polymer material such as polyolefin or polyester is mixed with carbon nanotubes to prepare a mixture which is in turn drawn to orient the carbon nanotubes, thereby reinforcing the high polymer material.

Nonpatent Document 1: Ph. Avouris et al. “Applied Surface Science 141” (1999) pp. 201-209

Patent Document 1: Published Japanese Translation of PCT International Publication of Patent Application No. 2002-544356

### DISCLOSURE OF THE INVENTION

### Problems that the Invention is to Solve

It, however, is practically difficult in view of the fabrication process to fixedly arrange carbon nanotubes of nanostructure, which is an inorganic electronic functional material, on an extremely small TFT by operating the manipulator of an atomic force microscope like the case of the thin-film. transistor 63 of Nonpatent Document 1. Also, formation of a semiconductor layer composed of nanotubes on a pliable flexible substrate such as plastic substrates is difficult to proceed.

In fact, it is impractical to use, as an electronic functional material orientation method, the orientation method in which nanotube molecules of substantially one-dimensional shape are aligned on a substrate one by one, using an orientation operating means such as an atomic force microscope.

The prior art technique disclosed in Patent Document 1 has presented the problem that even if carbon nanotubes that are an electronic functional material are mixed with an orientation material such as high polymer material and this orientation material is oriented through orientation treatment thereby orienting the nanotubes (i.e., electronic functional material), the high polymer material serving as an orientation material remains as a residuum between the carbon nanotube molecules with the result that the characteristics of the nanotubes as the electronic functional material deteriorate.

### Means for Solving the Problem

The invention is directed to overcoming the problem described above. To solve this problem, the organic semiconductor or nanotubes, which are an electronic functional material, need to be oriented and aligned in a specified direction by a simplified orientation method such that the inherent properties of the electronic functional material are educed, whereby the flow of electrons and holes is smoothed and in consequence, improved electric properties such as carrier mobility are obtained.

Therefore, a primary object of the invention is to provide a simplified orientation method for an electronic functional material according to which electronic functional material molecules and matrix material molecules are mixed to be oriented in a more desirable condition and then the matrix material molecules for orienting the electronic functional material are removed, so that the properties of the electronic functional material can be further improved. Another object of the invention is to provide an electronic functional material thin film and a fabrication method thereof, the properties of the thin film being improved by use of the above orientation method. Still another object of the invention is to provide a thin-film transistor and a fabrication method thereof, the thin-film transistor employing the electronic functional material or the electronic functional material thin film as a semiconductor layer.

To achieve the above objects, there is provided, according to the invention, a method of orienting an electronic functional material, the method comprising:

a mixed material preparation step of preparing a mixed material from an electronic functional material and a matrix material used for orientating the electronic functional material;

an orientation step of orientating the mixed material; and

a matrix material removal step of removing the matrix material from the mixed material which has been oriented. With this method, the molecules of the electronic functional material are oriented in a more desirable condition and the inherent properties of the electronic functional material are easily improved by removing the matrix material molecules present between the molecules of the electronic functional material.

The electronic functional material may contain an organic semiconductor compound.

The electronic functional material may contain nanotubes.

The mixed material preparation step may include a mixed material layer formation step of forming a mixed material layer containing the mixed material.

In the orientation step, the mixed material may be oriented by at least any of drawing, shear deformation and liquid crystal orientation.

In the matrix material removal step, the matrix material may be removed by at least either heating or etching.

The matrix material may contain a heat developable type resist material which is monomerized, sublimated and developed by heating after exposed to ultraviolet rays or irradiated with an electronic beam.

The matrix material may contain a photosensitive polyphthalaldehyde base material.

According to the invention, there is provided a method of fabricating an electronic functional material thin film by use of the electronic functional material orientation method of claim 1.

According to the invention, there is provided a method of fabricating a thin-film:transistor, wherein an electronic functional material thin film that constitutes a semiconductor layer is formed by the electronic functional material thin film fabricating method of claim 9.

The electronic functional material thin film of the invention is produced by the electronic functional material thin film fabricating method of claim 9. This ensures preservation of the inherent properties of the electronic functional material.

The thin film transistor of the invention has a semiconductor layer composed of the electronic functional material thin film of claim 11. This enables the semiconductor layer to preserve the inherent properties of the electronic functional material.

These objects as well as other objects, features and advantages of the invention will become apparent to those skilled in the art from the following description with reference to the accompanying drawings.

### EFFECTS OF THE INVENTION

The invention has the effect of providing a simplified orientation method which comprises the steps described above and improves the properties of the electronic functional material; an electronic functional material thin film that is improved in its properties by utilizing the orientation method and a fabrication method thereof; and a thin-film transistor that utilizes the electronic functional material or the electronic functional material thin film as a semiconductor layer and a fabrication method thereof.

### BRIEF DESCRIPTION OF DRAWINGS

FIG. 1 is a flow chart showing a flow of an orientation method for an electronic functional material according to the invention.

FIG. 2 is a sectional view diagrammatically illustrating a configuration of a semiconductor device having an electronic functional material thin film according to a first embodiment of the invention.

FIGS. 3(a) to 3(d) are sectional views conceptually illustrating the steps of a method of fabricating an electronic functional material thin film according to the first embodiment of the invention.

FIGS. 4(a) to 4(d) are sectional views conceptually illustrating the steps of a method of fabricating an electronic functional material thin film according to a second embodiment of the invention.

FIGS. 5(a) and 5(b) are sectional views conceptually illustrating a method of fabricating a thin-film transistor according to a third embodiment of the invention.

FIG. 6 is a plan view conceptually illustrating a structure of an image display unit according to a fourth embodiment of the invention.

FIG. 7 is a sectional view conceptually illustrating a structure of a prior art thin-film transistor that uses carbon nanotubes as a semiconductor layer.

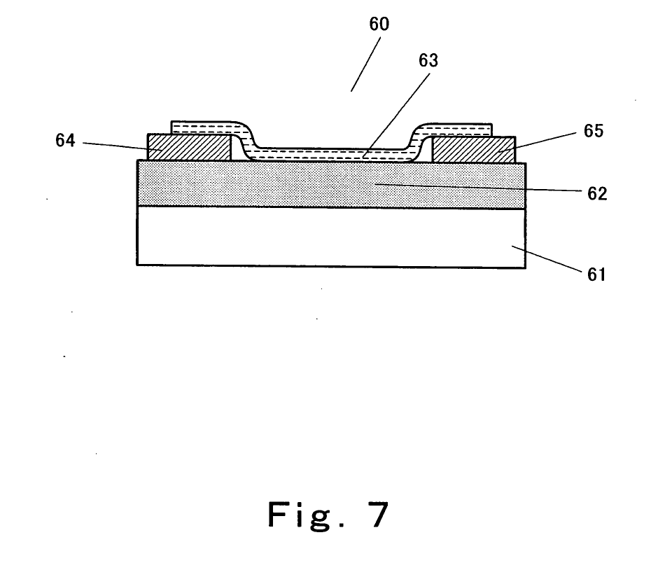

### EXPLANATION OF REFERENCE NUMERALS

1, 11: electronic functional material thin film

2, 61: substrate

3, 13: mixed material layer

4: matrix material

5: organic semiconductor compound

6, 7: electrode

9: roll coater

15: carbon nanotube material

20, 60: thin-film transistor

21: organic semiconductor layer

23, 62: gate insulating film

25: gate electrode

26, 64: source electrode

27, 65: drain electrode

51: image display unit

52: plastic substrate

53: row electrode

54: column electrode

55: intersection

56a, 56b: driving circuit

57: control circuit

58: display panel

63: semiconductive carbon nanotubes

201: semiconductor device

### BEST MODE FOR CARRYING OUT THE INVENTION

Referring now to the accompanying drawings, preferred embodiments of the invention will be hereinafter described. In the figures described below, those parts that are substantially equivalent or function substantially similarly to one another are indicated by the same numerals and redundant explanations on them will be avoided.

### CONCEPT OF THE INVENTION

First of all, the concept of the invention will be explained.

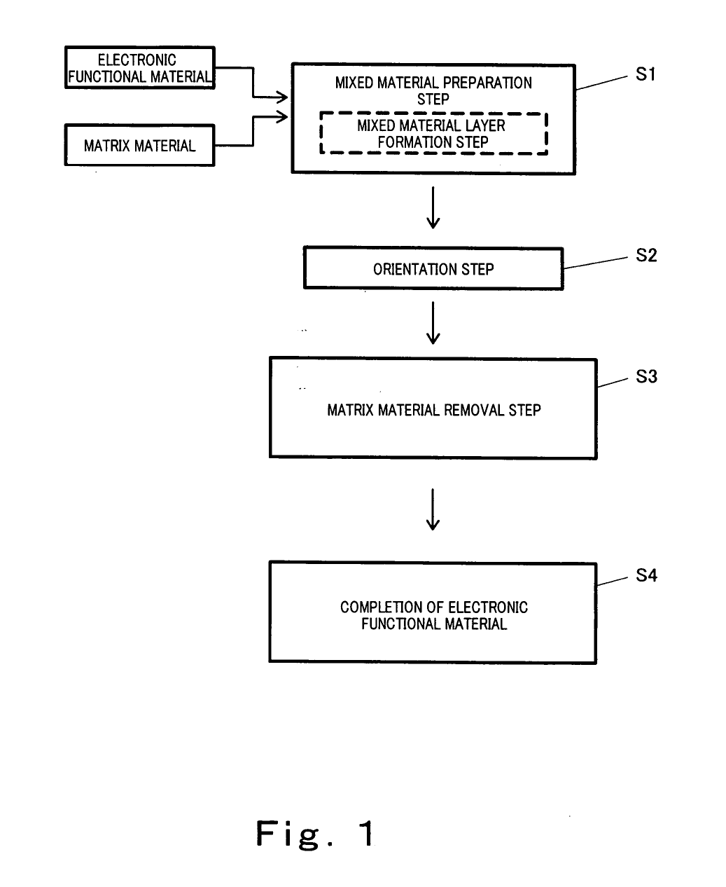

FIG. 1 is a flow chart showing a flow of an orientation method for an electronic functional material according to the invention.

Herein, there will explained, as one form of the invention, an orientation method for an electronic functional material which method is incorporated into a method of fabricating a thin film of electronic functional material (hereinafter referred to as “electronic functional material thin film”).

As shown in FIG. 1, in the orientation method for an electronic functional material, a mixed material preparation step is first performed (Step S1). In this mixed material preparation step, a mixed material is prepared by mixing an electronic functional material with a matrix material that is used for the purpose of orientating the electronic functional material. Alternatively, a mixed material, which is composed of an electronic functional material mixed with a matrix material beforehand (hereinafter simply referred to as “mixed material”), may be used. In this case, these materials may be blended with a solvent such as water or an organic solvent for easy mixing.

Herein, the “electronic functional material” means a material that can exert a useful function when current or an electric field acts thereon. As such an electronic functional material, there may be used organic material base organic semiconductor compounds and inorganic material base nanotubes which can transport electrons and holes in a good condition. It is also possible to use composite electronic functional materials produced by mixing an organic material base organic semiconductor compound and inorganic material base nanotubes.

The matrix material is necessary for orienting the electronic functional material mixed with the matrix material in a specified direction. More concretely, it tangles with the molecules of the electronic functional material so that the electronic functional material is oriented and aligned in substantially matrix form. However, if the matrix material remains, it degrades the properties of the electronic functional material thin film.

Next, in the mixed material layer preparation step, the mixed material thus prepared is applied onto, for instance, a substrate by means of printing, spin-coating, injection, filling, ink jet, spraying or the like, thereby forming a mixed material layer containing the mixed material.

Then, an orientation step (Step S2) is performed. In this orientation step, the mixed material layer formed in the mixed material preparation step is oriented in a substantially uniform specified direction through orientation treatment. In cases where this mixed material layer is similar to a resin film separated from the substrate, the mixed material layer is drawn. More specifically, the matrix material molecules contained in the mixed material layer are drawn in a substantially uniform direction in a plane. Thereby, the molecules of the electronic functional material within the mixed material layer are oriented (aligned) along with the molecules of the oriented matrix material in a substantially specified direction. Where the mixed material layer is formed on and in adheres to the substrate, the mixed material layer may be oriented by shear deformation using, for instance, a roll coater. Where the mixed material layer is in the form of a liquid, the mixed material layer is formed and oriented by liquid crystal orientation treatment. In the case of the liquid crystal orientation treatment, it is required that a liquid crystal material be used as the matrix material, an oriented film such as, for example, a polyimide oriented film be formed on the surface of the substrate, and this film be subjected to orientation.

Then, a matrix material removal step (Step S3) is performed. In this matrix material removal step, at least the matrix material is removed from the mixed material layer which has been subjected to the orientation treatment in the orientation step. More concretely, the mixed material layer is heated (baked) or etched to sublimate or dissolve the matrix material so that the matrix material is removed from the layer. Where the matrix material is sublimated by heating, the matrix material needs to be a heat-developable material. Where the matrix material is dissolved and removed by etching, it is necessary to use a developing solution capable of dissolving and removing the matrix material. Thus, this step makes it possible to remove the matrix material from the mixed material layer, the matrix material being unnecessary for preserving the properties of the electronic functional material thin film although it orients the electronic functional material.

Thus, by accomplishing the above steps, an electronic material thin film is formed (Step S4) from which the matrix material has been removed and in which the electronic functional material is oriented in a specified direction.

In the orientation method for an electronic functional material shown in FIG. 1, the order of steps and time series may be altered and other steps may be added according to need.

According to the orientation method for an electronic functional material of the invention described above, the molecules of the electronic functional material comprising an organic semiconductor, nanotubes or the like are oriented in a desirable condition by the matrix material and the matrix material molecules existing between the oriented electronic functional material molecules are removed. With such a simplified process, an electronic functional material thin film can be easily produced substantially without spoiling the properties of the electronic functional material.

Next, embodiments of the invention will be explained one by one.

### First Embodiment

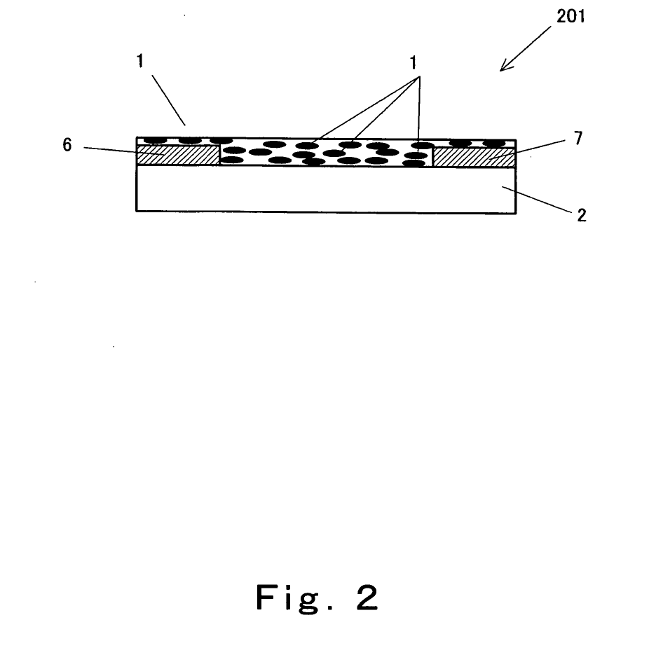

FIG. 2 is a sectional view diagrammatically illustrating a configuration of a semiconductor device having an electronic functional material thin film according to a first embodiment of the invention.

As illustrated in FIG. 2, a semiconductor device 201 has a substrate 2. A pair of electrodes 6, 7 are formed so as to face each other with a space therebetween on the substrate 2. An electronic functional material thin film 1 is laid over the pair of electrodes 6, 7 and over the surface of the substrate 2 located between the pair of electrodes 6, 7.

The electronic functional material thin film 1 of the first embodiment is substantially constituted by an oriented organic semiconductor compound 5. Herein, the organic semiconductor compound 5 consists of pentacene described later.

Next, there will be explained a method of fabricating the electronic functional material thin film 1 having the above-described configuration.

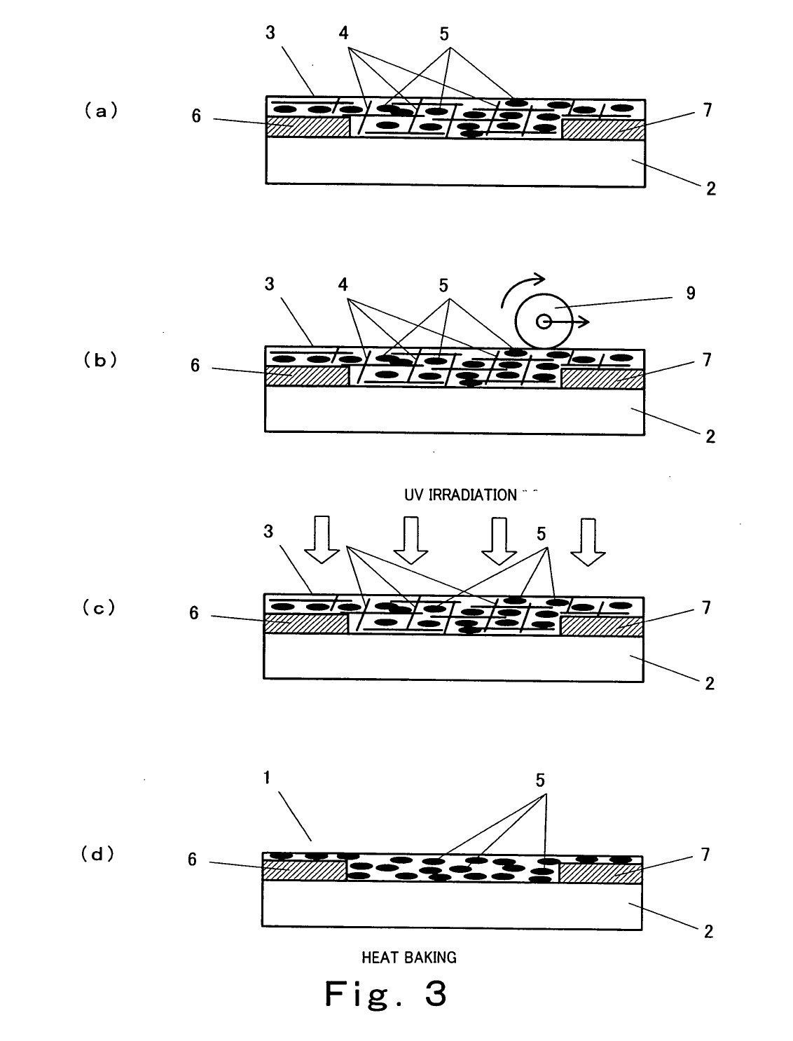

FIGS. 3(a) to 3(d) are sectional views conceptually illustrating the steps of a method of fabricating an electronic functional material thin film according to the first embodiment of the invention.

In FIG. 1, in the mixed material preparation step, pentacene which is an organic semiconductor compound serving as the electronic functional material is blended with a matrix material at a mixing ratio of about 1:1, thereby preparing a mixture of the organic semiconductor material and the matrix material. Concretely, the pentacene used herein has alkyl substituents, more preferably, at least n=1-5 alkyl substituents in the following chemical formula (hereinafter referred to as “Chemical Formula 1”) and is soluble in an organic solvent.

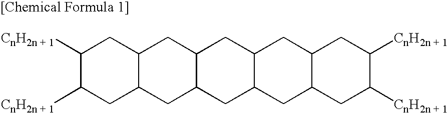

The matrix material is a mixture prepared by adding PCPA (R═Cl) or PBPA (R═Br) and several % of triphenylsulfoniumhexafluoroantimonate to cyclohexanone. PCPA (R═Cl) or PBPA (R═Br) is a polyphthalaldehyde base resist material represented by the following chemical formula (hereinafter referred to as “Chemical Formula 2”). Triphenylsulfoniumhexafluoroantimonate is a photoinitiator represented by the following chemical formula (hereinafter referred to as “Chemical Formula 3”) and added in order to impart photosensitivity. In addition to these additives, other additives such as sensitizers may be added according to need. Further, other organic solvents may be added according to need in order to facilitate blending of the materials.

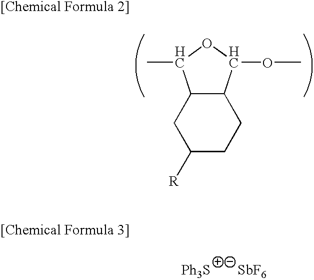

As shown in FIG. 3(a), as the mixed material layer formation step, the mixed material prepared in the mixed material preparation step is applied by e.g., spin coating onto the substrate 2 with a coating thickness of about 1 μm, the substrate 2 having the pair of electrodes 6, 7 opposed to each other with a space therebetween, and then this substrate 2 is preliminarily baked at about 100° C. to evaporate the organic solvent, thereby forming a mixed material layer 3 containing the matrix material 4 and the organic semiconductor compound 5.

As shown in FIG. 3(b), as the orientation step, the mixed material layer 3 is shear-deformed in a specified direction under a shearing stress by means of a roll coater 9. Then, as illustrated in FIG. 3(b), the molecules of the matrix material 4 containing the polyphthalaldehyde base resist material represented by Chemical Formula 2 are drawn in a specified direction and oriented (aligned) and at the same time, the organic semiconductor compound 5, which is composed of pentacene represented by Chemical Formula 1 and enclosed by the oriented molecules of the matrix material 4, is also oriented (aligned) in a specified direction substantially along with the molecules of the matrix material 4.

As shown in FIG. 3(c), as the matrix material removal step, ultraviolet (UV) rays having a wavelength of 254 nm and a weak strength of 0.38 mJ/m² are projected to the oriented mixed material layer 3, thereby exposing the mixed material layer 3 to the rays. Alternatively, electron beam energy of the same level as of the ultraviolet rays may be projected in place of the ultraviolet rays. While a material which is not self-developed under irradiation of ultraviolet rays is used as the matrix material 4 in this embodiment, slight self development is acceptable.

Thereafter, in FIG. 3(d), the mixed material layer 3 (more precisely, the substrate 2) irradiated with the ultraviolet rays is heat-baked at about 160° C. for 2 minutes. Then, the oriented matrix material 4, which is composed of the polyphthalaldehyde base resist material and contained in the mixed material layer 3, is monomerized through the irradiation with the ultraviolet rays and heating so that it returns to a monomer aldehyde, thereby causing thermal development in which it sublimes and vaporizes from the substrate 2. Thereby, the matrix material 4, which contributes to the orientation of the organic semiconductor compound 5 but is not necessary for preserving the properties of the resultant film, is removed from the mixed material layer 3, so that the layer of the organic semiconductor compound 5 oriented in the specified direction is left on the substrate 2. As a result, the electronic functional material thin film 1 constituted by the organic semiconductor layer containing the organic semiconductor compound 5 is formed. In this case, the molecules of the organic semiconductor compound 5 oriented in the specified direction are mutually closely compacted (packed) by heat baking so as to form the strong electronic functional material thin film 1 which is an organic semiconductor film mostly composed of pentacene and having a thickness of about 0.5 μm.

Next, there will be explained the properties of the electronic functional material thin film 1 formed in the above way and having the above structure.

As Comparative Example 1, the inventors prepared an electronic functional material thin film, which was low in orientation and had a residuum, from a pentacene organic semiconductor compound, using the prior art method. Then, they compared this thin film with the electronic functional material thin film 1 of the first embodiment. In this comparison, the thin film of Comparative Example 1 and the thin film of the first embodiment had substantially the same sectional area and the same electrode-to-electrode distance, and their electric conductivities were measured. As a result, it was found that the electric conductivity of the electronic functional material thin film 1 of the first embodiment was about 10 times that of Comparative Example 1. It is assumed from the above result and the fact that the carrier mobility of Comparative Example 1 is about 0.1 cm²/Vs, the carrier mobility of the electronic functional material thin film 1 of the first embodiment is as high as about 1 cm²/Vs. The thin film of the first embodiment has a level as high as that of a material in which the molecules of the organic semiconductor compound 5 have been oriented in a good condition on the molecular level to be improved in its charge transport condition.

As has been described above, since the electronic functional material thin film 1 of the first embodiment is formed by orienting the molecules of the organic semiconductor compound 5 in a desirable condition and removing the molecules of the unnecessary matrix material 4 present between the molecules of the organic semiconductor compound 5, it exhibits excellent properties as a semiconductor layer using the electronic functional material.

In the method of fabricating an electronic functional material thin film according to the first embodiment, dry etching is performed using, as the matrix material 4, a heat developable resist material that can be sublimated and removed by heat baking, so that the orientation of the molecules of the organic semiconductor compound 5, which is the electronic functional material left on the substrate, is hardly disturbed and as a result, a semiconductor layer having good properties can be obtained.

In the foregoing description, the matrix material 4 is monomerized so as to sublime and evaporate so that it is removed from the substrate 2. Therefore, it is desirable to provide the developer with the function of getting rid of the molecules of the matrix material 4 which have been removed.

In addition, while a polyphthalaldehyde base material to which photosensitivity is given by addition of a photoinitiator is described as one example of the matrix material 4 in the above description, other materials may be used as the matrix material 4 provided that they are heat-developable photosensitive resist materials that can be monomerized and sublimated by heating, and are more preferably sublimable, heat-developable photosensitive resist materials composed of substantially bar-like compound molecules.

Resists formed by adding onium salt to polyphthalaldehyde cause depolymerization at room temperature. Therefore, such self-developable resists that can be developed without heat baking after exposure to ultraviolet rays may be used as the matrix material 4, although a material that is heat-developable by heat baking after exposure to ultraviolet rays is used as the matrix material 4 in the foregoing description.

While the mixing ratio between the organic semiconductor compound 5 and the matrix material 4 is about 1:1 in the foregoing description, any other ratios may be employed according to desired properties.

In addition, the ultraviolet irradiation conditions and heating conditions for the mixed material layer 3 are not limited to those described earlier but other conditions may be employed as far as they are suited to the above-described materials.

While pentacene is used as the organic semiconductor compound 5 in the foregoing description, organic semiconductor compounds such as tetracene, thiophene oligomer derivatives, phenylene derivatives, phthalocyanine compounds, polyacetylene derivatives, polythiophene derivatives and cyanine dye may be used. It should be noted that examples of the organic semiconductor compound 5 are not limited to these materials.

While an organic material base organic semiconductor compound 5 is used as the electronic functional material in the foregoing description, composite electronic functional materials formed by mixing an organic material base organic semiconductor compound with inorganic material base nanotubes may be used.

Although the mixed material layer 3 is formed by spin-coating the prepared mixed material in the mixed material layer formation step of the mixed material preparation step, the mixed material layer 3 may be formed by other coating methods such as printing, injection, filling, ink jet and spraying.

Although the matrix material 4 is oriented by shear-deforming the mixed material layer 3 formed on the substrate 2 with a roll coater 9, it may be drawn and oriented in such a way that the mixed material layer 3 is exfoliated from the substrate 2 and then, both ends of the exfoliated mixed material layer 3 are pulled in opposite horizontal directions with a substantially constant force.

### Second Embodiment

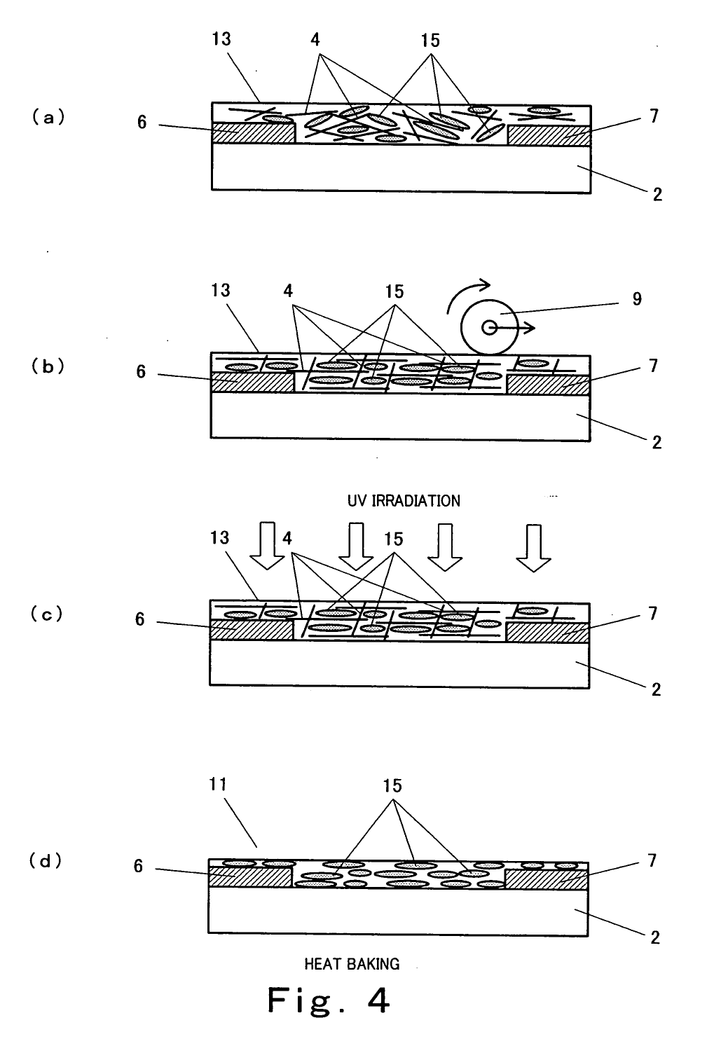

FIGS. 4(a) to 4(d) are sectional views conceptually illustrating the steps of a method of fabricating an electronic functional material thin film according to a second embodiment of the invention.

As shown in FIG. 4(d), in the electronic functional material thin film 11 of the second embodiment, the electronic functional material consists of a carbon nanotube material. Except this point, the second embodiment is the same as the first embodiment.

Concretely, the carbon nanotubes are semiconductive carbon nanotubes having a length of about 1 to 3 μm and diameter of 1 to 5 nm and selected from mixed-type carbon nanotube materials. It should be noted that the carbon nanotubes used may be of other types than those just described above.

Next, there will be explained the method of fabricating the electronic functional material thin film 11 according to the second embodiment.

As shown in FIG. 4(a), as the mixed material preparation step, a mixed material is prepared by mixing a semiconductive carbon nanotube material 15 with a matrix material 4 at a mixing ratio of about 0.5:1. The matrix material 4 is prepared by adding the photoinitiator represented by Chemical Formula 3 to the polyphthalaldehyde base resist material represented by Chemical Formula 2 to give photosensitivity. An organic solvent may be used according to need.

Then, in the mixed material layer formation step, a mixed material is applied by e.g., spin coating onto the substrate 2 with a coating thickness of about 0.5 μm, the substrate 2 having, thereon, the electrodes 6, 7 opposed to each other with a space therebetween. The mixed material is then subjected to preliminary baking at about 100° to form a mixed material layer 13.

As shown in FIG. 4(b), as the orientation step, the mixed material layer 13 is shear-deformed in a specified direction under a shear stress, using the roll coater 9. Then, the molecules of the matrix material 4 composed of the polyphthalaldehyde base resist material represented by Chemical Formula 2 are drawn and oriented in a specified direction and at the same time, the semiconductive carbon nanotube material 15 surrounded by the oriented molecules of the matrix material 4 is also oriented in the specified direction substantially along with the molecules of the matrix material 4.

As shown in FIG. 4(c), as the matrix material removal step, ultraviolet (UV) rays having a wavelength of 254 nm and a comparatively weak strength of 0.38 mJ/m² are projected to the oriented mixed material layer 13 thereby exposing the mixed material layer 13 to the rays.

As shown in FIG. 4(d), the mixed material layer 13 irradiated with the ultraviolet rays is heat-baked at about 160° C. for 2 minutes. Then, the matrix material 4 composed of the oriented polyphthalaldehyde base resist material and contained in the mixed material layer 13 is monomerized, returning to monomer aldehyde through the irradiation with the ultraviolet rays and heating, so that thermal development occurs in which the matrix material 4 sublimes and evaporates from the substrate 2. Thereby, the matrix material 4, which causes orientation of the carbon nanotube material 15 but is unnecessary for preserving the properties of the resultant film, can be removed from the mixed material layer 13, so that the layer of the carbon nanotube material 15 oriented in the specified direction remains on the substrate 2. As a result, the electronic functional material thin film 11 composed of the inorganic semiconductor layer of the carbon nanotube material 15 is formed. In this case, the molecules of the carbon nanotube material 15 oriented in the specified direction are more compactly packed by heat baking and the electronic functional material thin film 11, which is a nanotube semiconductor layer having good properties, is formed.

Next, there will be explained the properties of the electronic functional material thin film 11 having the above configuration and fabricated through the above process.

The inventors prepared, as Comparative Example 2, an electronic functional material thin film which had low orientation and contained a residuum, from semiconductive carbon nanotubes with the prior art method, and then compared it with the electronic functional material thin film 11 prepared according to the second embodiment. In this comparison, the thin film of Comparative Example 2 and the thin film of the second embodiment had substantially the same sectional area and the same electrode-to-electrode distance, and their electric conductivities were measured. It was found from the result of the comparison that the electric conductivity of the electronic functional material thin film 11 of the second embodiment was about five times that of Comparative Example 2. Assuming from this result and the fact that the carrier mobility of Comparative Example 2 is about 200 cm²/Vs, the carrier mobility of the electronic functional material thin film 11 of the second embodiment is as high as about 1000 cm²/Vs. The level of the properties of the second embodiment is substantially as high as that of a material in which the semiconductive carbon nanotubes have been orientated to be improved in its charge transport condition.

As described above, the electronic functional material thin film 11 of the second embodiment is formed such that the molecules of the semiconductive carbon nanotube material 15 are oriented in a better condition and the molecules of the unnecessary matrix material 4 present between the molecules of the semiconductive carbon nanotube material 15 are removed. Therefore, the electronic functional material thin film of the invention formed making use of semiconductive nanotubes exhibits good properties as a semiconductor layer using the electronic functional material.

Although the mixing ratio of the carbon nanotube material 15 and the matrix material 4 is about 0.5:1 in the foregoing description, other mixing ratios may be employed according to desired properties.

Ultraviolet ray projecting conditions and heating conditions for the mixed material 13 are set such that they may be suitable for the material used.

As the matrix material 4, etching-development-type photosensitive resists, which can be developed by an etching developing solution, may be used. In this case, the matrix material 4 is dissolved and removed by the etching developing solution.

Although inorganic material base carbon nanotubes are used as the electronic functional material 11 in the foregoing description, other inorganic material base semiconductor materials may be used as the electronic functional material 11.

Further, as the electronic functional material 11, composite electronic functional materials may be used which are composed of a mixture of an organic material base organic semiconductor compound and inorganic material base nanotubes.

### Third Embodiment

In each of the electronic functional material thin films according to the first and second embodiments, the molecules of the electronic functional material (e.g., an organic semiconductor compound and nanotubes) constituting the thin film are closely oriented in a desirable condition to attain improved filling density, whereby the density of the electronic junctions between the molecules of the electronic functional material can be increased and the electric conductivity and carrier mobility of the electronic functional material thin film can be further improved. As a result, they can be used as a conductive thin film (electronic functional material thin film) or semiconductor layer having excellent electric properties and utilized in fabrication of thin-film transistors, micro circuit devices and high-performance electronic device parts.

A third embodiment of the invention exemplifies the thin-film transistor in which the electronic functional material thin film 1 of the first embodiment is used as a semiconductor layer.

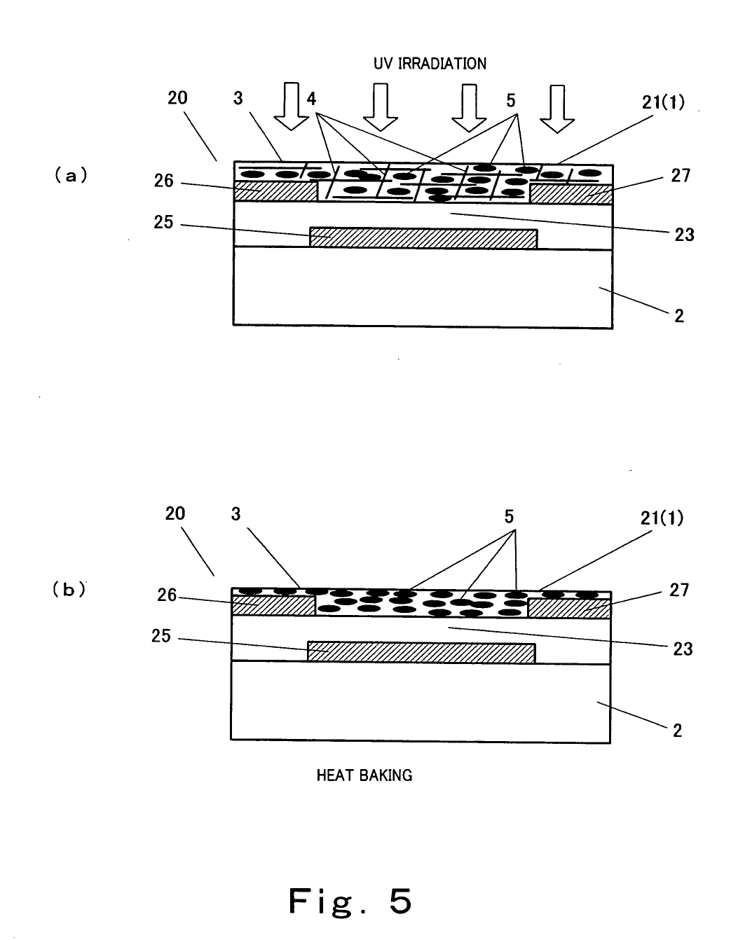

FIGS. 5(a) and 5(b) are sectional views conceptually illustrating a method of fabricating a thin-film transistor according to the third embodiment of the invention.

As shown in FIG. 5(b), a thin-film transistor 20 according to the third embodiment has the substrate 2. A gate electrode 25 made from gold or the like is formed on the substrate 2. A gate insulating film 23 made from oxide silicon is formed so as to cover the gate electrode 25 and other surface areas of the substrate 2 than the area where the gate electrode 25 is formed. Formed on the gate insulating film 23 are a source electrode 16 and a drain electrode 27 which are made from gold and located at both sides, respectively, of the gate electrode 25 in plan view. An organic semiconductor layer 21 is formed so as to cover the gate insulating film 23 located between the source electrode 16 and the drain electrode 27, the source electrode 16 and the drain electrode 27. The organic semiconductor layer 21 is constituted by the electronic functional material thin film 1 of the first embodiment.

Next, a method of fabricating the thin-film transistor 20 of the above configuration will be described.

Referring to FIG. 5(a), a pattern is formed on the substrate 2 from an electrode material such as gold by the thin-film formation technique, photolithographic technique or lift-off technology, thereby forming the gate electrode 25 at the bottom. Next, the gate insulating film 23 is formed from oxide silicon so as to cover the gate electrode 25. Then, patterns are formed on the gate insulating film 23 from an electrode material such as gold such that the patterns face each other with the gate electrode 25 sandwiched therebetween in plan view, whereby the source electrode 26 and the drain electrode 27 are formed.

Then, the organic semiconductor layer 21, which is the electronic functional thin film 1 described earlier in the second embodiment, is formed in the following manner over the gate insulating film 23 so as to cover the source electrode 26 and the drain electrode 27, whereby the bottom gate thin-film transistor 20 such as shown in FIG. 5(b) is obtained. It should be noted that a protective film etc. is not shown in the drawing for simplicity.

In FIG. 5(a), the organic semiconductor layer 21 constituted by the electronic functional material thin film 1 and serving as a semiconductor layer is formed similarly to the first embodiment.

Specifically, the mixed material described below is applied onto the surface of the gate insulating film 23 between the source electrode 26 and the drain electrode 27 and onto at least part of the source electrode 26 and the drain electrode 27.

The mixed material is produced by blending the organic semiconductor compound 5 and the matrix material 4 at a mixing ratio of about 1:1. The organic semiconductor compound 5 is composed of pentacene represented by Chemical Formula 1 and serving as an electronic functional material. The matrix material 4 is composed of a polyphthalaldehyde base resist material represented by Chemical Formula 2 to which several % of the photoinitiator represented by Chemical Formula 3 is added so as to impart photosensitivity. The mixed material of the matrix material 4 and the organic semiconductor compound 5 is applied onto the surface of the gate insulating film 23 and onto at least part of the source electrode 26 and the drain electrode 27 by a coating method such as spin coating, printing or ink jet, with a coating thickness of about 1 μm. Then, the mixed material is subjected to preliminary baking at about 100° C., thereby forming the mixed material layer 3. Thereafter, shear stress is applied to the mixed material layer 3 by a roll coater (not shown) in a specified direction (e.g., the direction of connecting the source electrode 26 and the drain electrode 27), so that the mixed material layer 3 is shear-deformed. Then, the mixed material layer 3 is irradiated with ultraviolet rays as shown in FIG. 5(a).

Then, the mixed material layer 3 is heat-baked at about 160° C. for two minutes as shown in FIG. 5(b). Then, the oriented matrix material 4 in the mixed material layer 3 is monomerized by the ultraviolet ray irradiation and heating, so that it returns to the monomer. The monomer then sublimes and evaporates through thermal development so that it is removed from the mixed material layer 3. That is, the matrix material 4, which causes orientation of the organic semiconductor compound 5 but is unnecessary for preserving the properties of the organic semiconductor layer 21, is removed by this matrix material removal step.

Thereby, the molecular layer of the organic semiconductor compound 5 oriented in the specified direction is left on the gate insulating film 23, the source electrode 26 and the drain electrode 27, constituting the organic semiconductor layer 21 that is the electronic functional material thin film 11. Thus, the thin-film transistor 20 having the organic semiconductor layer 21 as a semiconductor layer is fabricated.

In the thin-film transistor 20, the organic semiconductor layer 21 is formed such that charge transport performance is improved by orienting the molecules of the organic semiconductor compound 5 in a good condition and the molecules of the unnecessary matrix material 4 present between the molecules of the oriented organic semiconductor compound 5 are removed. The organic semiconductor layer 21 thus formed is further improved in the characteristics inherent to the organic semiconductor material and exhibits excellent properties as a semiconductor layer.

It was found from the result of a test that the ON current of the thin-film transistor 20 of this embodiment was about 10 times the ON current of the thin-film transistor having an organic semiconductor layer which was prepared by the prior art technique from the organic semiconductor material of the same characteristics and which had low orientation and a residuum.

Assuming from this result and the fact that the carrier mobility of the channels of the thin-film transistor having the conventional organic semiconductor layer is about 0.1 cm²/Vs, the carrier mobility of the channels of the thin-film transistor 20 of this embodiment is as high as about 1 cm²/Vs.

As described above, the thin-film transistor 20 according to the third embodiment satisfactorily preserves the characteristics inherent to the electronic functional material and exhibits high carrier mobility in its channels, because the filling density of the semiconductor layer 21 is improved by compactly orienting the molecules of the electronic functional material of the electronic functional material thin film 1 that constitutes the semiconductor layer 21 in a desirable condition and removing the molecules of the unnecessary matrix material 4 present between the molecules of the electronic functional material. Therefore, the thin-film transistor 20 of the third embodiment can be used as a thin-film transistor with a semiconductor layer having excellent properties which is applicable to micro circuit devices and high-performance electronic devices.

Next, a modification of the third embodiment will be described.

In a thin-film transistor according to this modification, the mixture layer 3 is formed by blending a liquid crystal organic semiconductor compound (e.g., 4′-npentyl-4-cyanobiphenyl5CB) and semiconductive nanotubes (e.g., carbon nanotubes). In order to orient the liquid crystal organic semiconductor compound of the mixture layer 3 in a specified direction, a polyimide oriented film, for example, has been formed over the gate insulating film 23 located between the source electrode 26 and the drain electrode 27 and over the source electrode 26 and the drain electrode 27. This polyimide oriented film has been subjected to orientation treatment and the nanotubes are oriented together with the liquid crystal organic semiconductor compound according to this orientation treatment. This mixture layer 3 is rapidly heated to 250° C. under a reduced pressure of about 1.013 kPa (0.01 barometric pressure) so that 5CB evaporates and only the nanotubes are left in the mixture layer 3 while substantially keeping its orientation condition. The remaining semiconductive nanotubes constitute the semiconductor layer of the thin-film transistor.

While the semiconductor layer of the thin-film transistor 20 is constituted by the electronic functional material thin film 1 of the first embodiment in the foregoing description, it may be constituted by the electronic functional material thin film 11 of the second embodiment.

It is also possible to use a composite semiconductor material prepared by combining an organic semiconductor compound serving as an electronic functional material with semiconductive carbon nanotubes.

While a polyphthalaldehyde base material to which a photoinitiator is added to impart photosensitivity is used as the matrix material 4 in the foregoing description, other materials may be used as far as they are heat-developable photosensitive resist materials that can be monomerized and sublimated by heating.

While a heat-developable photosensitive resist material that can be monomerized and sublimated by heating is used as the matrix material 4 in the foregoing description, an etching-developable photosensitive resist that can be developed by an etching developing solution may be used. In this case, the matrix material 4 is dissolved and removed by an etching solution.

While the mixing ratio between the organic semiconductor compound 5 and the matrix material 4 is about 1:1 in the foregoing description, other mixing ratios may be employed according to desired properties. In addition, ultraviolet ray irradiating conditions and heating conditions may be arbitrarily set for the mixed material as far as they are suitable for the material.

While the invention has been described in the context of a bottom gate thin-film transistor in which the gate electrode is formed at the bottom of the gate insulating film on the substrate, it is also possible to apply the invention to a top gate thin-film transistor in which the gate electrode is formed on top of the gate insulating film on the substrate.

In the thin-film transistors constructed according to the embodiments of the invention, materials which are electrically conductive and do not react with the substrate nor the semiconductor may be used for forming the gate electrode, the source electrode and the drain electrode. Examples of the gate materials include doped silicon; precious metals such as gold, silver, platinum, platina and palladium; and alkali metals/alkaline earth metals such as lithium, cesium, calcium and magnesium. In addition to these metals, metals such as copper, nickel, aluminum, titanium, molybdenum and alloys thereof may be used. In addition, electrically conductive organic materials such as polypyrrole, polythiophene, polyaniline and polyphenylenevinylene may be used. Since the gate electrode is operable even if it has greater electric resistance than other electrodes, a material different from that of the source electrode and the drain electrode may be used for the gate electrode for easy fabrication.

For the gate insulating film, materials that are electrically insulated and do not react with the substrate, the electrodes and the semiconductor may be used. Apart from the soft materials listed earlier, silicon having a normal silicon dioxide film formed thereon may be used as the substrate and this silicon dioxide film may be utilized as the gate insulating film. Further, a thin layer of resin, which serves as the gate insulating film, may be formed after formation of the dioxide film. Alternatively, the gate insulating film may be formed by depositing a compound composed of other elements than those of the substrate and electrodes through CVD, vapor deposition or sputtering. The gate insulating film may be formed by applying a solution of the above compound through coating, spraying or electrolyzation. It is known to use a substance of high dielectric constant as the material of the gate insulating film in order to reduce the gate voltage of the thin-film transistor. Ferroelectric compounds and compounds of high dielectric constant other than ferroelectric substances may be used as the material of the gate insulating film. The material of the gate insulating film is not limited to inorganic substances, but organic substances of high dielectric constant such as polyvinylidene fluoride group or polyvinylidene cyanide group may be used.

There is a future possibility that nanotubes made from other materials than carbon may be used.

### Fourth Embodiment

According to the electronic functional material thin film and thin-film transistor of the invention, since the conventional low-temperature thin film formation technique can be utilized for formation of the thin film or the semiconductor layer, resin films having pliability such as thin polyimide films may be employed as the substrate, in addition to flexible and supple plastic plates and thin glass substrates. For instance, substrates made from a polyethylene film, polystyrene film, polyester film, polycarbonate film, polyimide film, etc. may be used. Use of such substrates makes the invention applicable to pliable (flexible) paper displays or sheet displays having a plastic substrate or resin film substrate.

The fourth embodiment of the invention exemplifies paper-like (sheet-like) image display units employing the electronic functional material thin film or thin-film transistor of the invention.

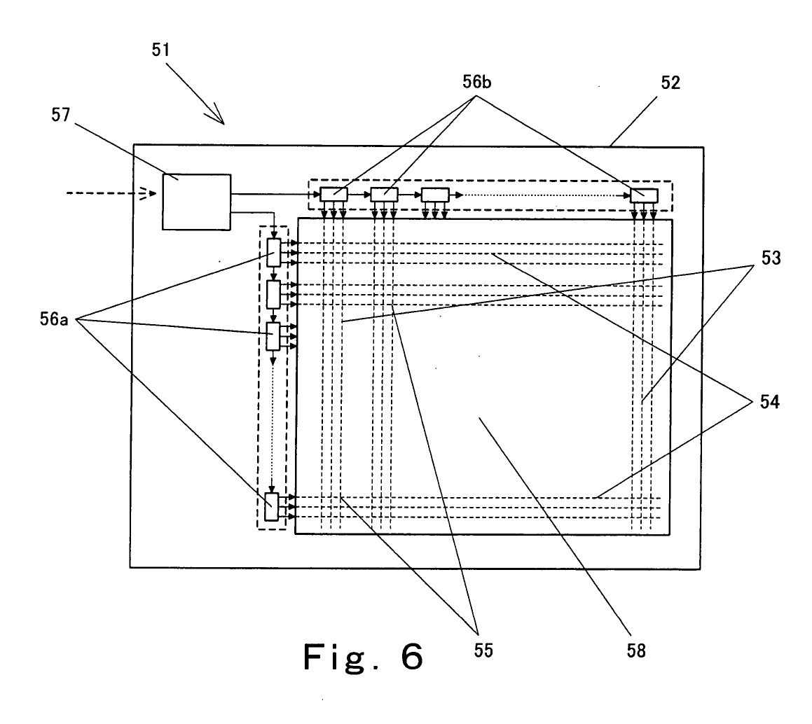

FIG. 6 is a plan view conceptually illustrating a structure of an image display unit according to the fourth embodiment of the invention.

In FIG. 6, an image display unit 51 of the active matrix type includes a plastic substrate 52. On the plastic substrate 52, a plurality of row electrodes 53 and a plurality of column electrodes 54 are formed so as to cross each other in plan view (grade-separated intersection). A display panel 58 is opposed to the plastic substrate 52 with a specified gap therebetween. Encapsulated in the gap is, for instance, an optical functioning material (i.e., a material that allows light to permeate and cuts off light or material that emits light and stops light emission). The region divided in matrix form by the row electrodes 53 and the column electrodes 54 in plan constitutes a picture element region. A switching element constituted by a minute thin-film transistor (not shown) is placed in the vicinity of the intersection between each row electrode 53 and each column electrode 54. This thin-film transistor is constituted by the thin-film transistor of the third embodiment. The row electrodes 53 and the column electrodes 54 are connected to driving circuits 56a, 56b, respectively. The driving circuits 56a, 56b are controlled by a control circuit (controller) 57.

In the image display unit 51, the driving circuits 56a, 56b controlled by the control circuit 57 apply voltage to the row electrodes 53 and the column electrodes 54 in response to an image signal. According to this voltage, the optical functioning material of each picture element is operated, thereby displaying an image corresponding to the image signal on the screen of the display panel 58. At that time, the switching elements corresponding to the picture elements are sequentially turned ON and OFF so that all the picture elements are sequentially scanned to display an image.

In this embodiment, the switching elements are each constituted by the thin-film transistor of the invention so that image signals can be turned ON and OFF with good properties. In addition, a rewritable paper-like or sheet-like display, which is a super-fine image display unit using a pliable substrate, can be put into practice. Further, the driving circuits 56a, 56b and the control circuit 57, which surround the display panel 58, are configured as a semiconductor circuit device including the electronic functional material thin film and the thin-film transistor, whereby the display panel 58 can be integrally formed with these circuits 56a, 56b, 57 and as a result, an image display unit such as a pliable rewritable paper-like electronic display or sheet display can be attained.

Concretely, the image display unit 51 is constituted by an image display unit of the liquid crystal display type, organic EL type, electrochromic display type (ECD), electrolytic precipitation type, electronic particulate type, or interferometric modulation type (MEMS).

It should be noted that the semiconductor circuit device including the electronic functional material thin film and thin-film transistor of the invention finds applications in the fields of portable devices, single-use devices (e.g., radio frequency identification tags (RFID tags)), electronic devices, robots, micro-mini medical instruments and other industrial fields.

Numerous modifications and alternative embodiments of the invention will be apparent to those skilled in the art in view of the foregoing description. Accordingly, the description is to be construed as illustrative only, and is provided for the purpose of teaching those skilled in the art the best mode of carrying out the invention. The details of the structure and/or function maybe varied substantially without departing from the spirit of the invention and all modifications which come within the scope of the appended claims are preserved.

### INDUSTRIAL APPLICABILITY

The method of orienting an electronic functional material of the invention is useful when orienting an electronic functional material substantially without spoiling its properties to readily obtain an electronic functional material thin film etc. having good carrier mobility.

The method of fabricating an electronic functional material thin film of the invention is useful when producing an electronic functional material thin film having good carrier mobility substantially without spoiling the properties of the electronic functional material.

The method of fabricating a thin-film transistor of the invention is useful when fabricating a thin-film transistor, which uses an electronic functional material thin film of good carrier mobility as a semiconductor layer, substantially without spoiling the properties of the electronic functional material.

The electronic functional material thin film of the invention is applicable to electronic devises etc. and useful as a pliable thin film having good carrier mobility.

The thin-film transistor of the invention is applicable to paper-like or sheet-like image display units etc. and useful as a thin-film transistor having good carrier mobility.

1. A method of orienting an electronic functional material, the method comprising:
a mixed material preparation step of preparing a mixed material from an electronic functional material and a matrix material used for orientating the electronic functional material;
an orientation step of orientating the mixed material; and
a matrix material removal step of removing the matrix material from the mixed material which has been oriented,
wherein, in the matrix material removal step, the matrix material is removed by at least either heating or etching.

2. The method of orienting an electronic functional material according to claim 1, wherein the electronic functional material contains an organic semiconductor compound.

3. The method of orienting an electronic functional material according to claim 1, wherein the electronic functional material contains nanotubes.

4. The method of orienting an electronic functional material according to claim 1, wherein the mixed material preparation step includes a mixed material layer formation step of forming a mixed material layer containing the mixed material.

5. The method of orienting an electronic functional material according to claim 1, wherein, in the orientation step, the mixed material is oriented by at least either drawing or shear deformation.

6. (canceled)

7. The method of orienting an electronic functional material according to claim 1, wherein the matrix material contains a heat developable type resist material which is sublimated and developed by heating after exposed to ultraviolet rays or irradiated with an electronic beam.

8. The method of orienting an electronic functional material according to claim 1, wherein the matrix material contains a photosensitive polyphthalaldehyde base material.

9. A method of fabricating an electronic functional material thin film by use of the electronic functional material orientation method of claim 1.

10. A method of fabricating a thin-film transistor, wherein an electronic functional material thin film that constitutes a semiconductor layer is formed by the electronic functional material thin film fabricating method of claim 9.

11. An electronic functional material thin film produced by the electronic functional material thin film fabricating method of claim 9.

12. A thin-film transistor having a semiconductor layer composed of the electronic functional material thin film of claim 11.

13. The method of orienting an electronic functional material according to claim 2, wherein the organic semiconductor compound is selected from the group consisting of pentacene, tetracene, thiophene oligomer derivatives, phenylene derivatives, phthalocyanine compounds, polyacetylene derivatives, polythiophene derivatives and cyanine dye.

14. The method of orienting an electronic functional material according to claim 1, wherein, in the orientation step, the mixed material is oriented by liquid crystal orientation.

15. The method of orienting an electronic functional material according to claim 1, wherein, in the matrix material removal step, the matrix material is removed through sublimation or evaporation by at least any of heating, light and depressurization.
